(19) United States
(12) Patent Application Publication
(10) Pub. No.: US 2008/0163917 A1
(43) Pub. Date: Jul. 10, 2008

(54) Transparent and Conductive Oxide Layer and Method of Making Same and Using it in a Thin-Film Solar Cell

(76) Inventors: Bernd Rech, Aachen (DE); Jurgen Hupkes, Viersen (DE); Oliver Kluth, Vilters (CH); Joachim Mueller, Fellbach (DE)

Correspondence Address: K.F. ROSS P.C., 5683 RIVERDALE AVENUE, SUITE 203 BOX 900, BRONX, NY, 10471-0900, US

(21) Appl. No.: 10/587,130

(22) PCT Filed: Jan. 18, 2005
(86) PCT No.: PCT/DE2005/000059

§ 371 Date: Dec. 28, 2007

(30) Foreign Application Priority Data
Jan. 23, 2004 (DE) 10 2004 003 760.4

(51) Int. Cl. H01L 31/042; H01B 1/00; C23C 14/32

(52) U.S. Cl. 136/244; 252/519.51; 204/192.15

(57) ABSTRACT

The invention relates to a method for the production of a conductive and transparent zinc oxide layer on a substrate by reactive sputtering. The process comprises a hysteresis region. Said method is characterised by the following steps: A doped metal Zn target is used, whereby the doping content of the target is less than 2.3 at-%, the heater is adjusted for the substrate in such a manner that a substrate temperature is adjusted to above 200° C. A dynamic deposition rate is adjusted to more than 50 nm*m/min, which corresponds to a static deposition rate which is greater than 190 nm/min, and a stabilised working point is selected within the unstable process range which is between the turning point between a stable, metal and unstable process and between the inflection point of the stabilised process curve.

The invention relates to a production method for a transparent, conductive zinc oxide film that is particularly suited for use in a thin-film solar array.

### STATE OF THE ART

Solar modules on the basis of the crystalline Si-wafer technology have proven their efficiency and reliability for years. Modules in thin-film technology that are based on semi-conductors and are applied across large surfaces on inexpensive substrates such as glass, metal or plastic films are not quite as established yet, however offer great cost savings potential due to the low material consumption and a large surface production.

In thin film technology, the cell and module development from hydrogenated amorphous silicon (α-Si:H) has progressed the farthest. The basis of these α-Si:H cell concepts generally is the p-i-n superstrate configuration with the layer sequence: substrate (glass)/transparent electrode (fluorine-doped tin oxide)/p-doped silicon carbide/undoped α-Si:H/n-doped α-Si:H metal. With this configuration, the sunlight penetrates from the substrate side into the active undoped absorber film that is typically 0.5 μm thick.

Silicon thin-film solar arrays require a transparent and conductive oxide layer (TCO layer) with a rough surface that scatters the incident light on the interface to the silicon in the solar cell such that the light passes through the solar cell multiple times. Optimally, the light is thus completely absorbed. On the laboratory scale, a zinc oxide (ZnO:Al) layer doped with aluminum was used as a film suitable for this, which was supposed to be produced inexpensively in large volume. In addition to the high permeability to visible light, these TCO layers must show a low resistivity level.

For the production of a rough TCO layer in principle two different methods are known from the literature. In the first case, a TCO layer of this type can be obtained through the specific growth of a rough film by suitably controlling it during production. This method is currently used to produce large-surface rough tin oxide layers with the help of a chemical vapor deposition (CVD) technique.

With the second method, initially a smooth TCO layer is produced that is subsequently correspondingly roughened by employing an etching process. The latter process is currently the topic of intense research and is being studied to be able to transfer it to the industrial production of large surfaces. In this method, zinc oxide, particularly zinc oxide doped with Al (ZnO:Al) is used. Corresponding films are produced by means of cathode evaporation (sputtering). Compared to the films grown in the raw state, they have significantly improved electrical and optical properties. These properties are influenced significantly by the process parameters, particularly the pressure and temperature levels used during the sputtering process. After the sputtering operation, these films however as a rule do not show the required roughness yet. This means that they are visually smooth and have no light scattering effect. These films are therefore generally subjected to a wet-chemical etching operation in a subsequent process step to roughen them.

Highly conductive and transparent ZnO films can be produced both through reactive sputtering techniques of metallic Zn and through non-reactive or partially reactive sputtering techniques of ceramic targets.

So far, RF sputtering from ceramic targets has been very successful. By bombarding it with Ar ions, a target of the respective film material is removed and deposited on a substrate disposed opposite thereof. The combination with other methods, for example the evaporation of individual elements (hybrid sputtering) or admixing of a reaction gas (N₂, O₂ or also ozone) to the plasma (reactive sputtering), is possible.

The literature [1] describes the related art for the large-surface production of ZnO films with the help of the reactive magnetron sputtering method. In this method, the substrate temperature is maintained at no more than 200° C. The operating point is optimized by controlling the generator output, thus allowing a specific oxygen particle pressure to be stabilized. In an optimization of the film for the subsequent etching process, the sputtering pressure was varied during production as a central parameter, as was the temperature within a closely defined range, however not above 200° C.

The ZnO layers described in [1] produced by reactive sputtering were developed with an industrial sputtering process and can also be etched. The layers produced this way have good conductivity and transparency properties, however they have the disadvantage of not showing optimal light-scattering properties. The efficiency of solar cells comprising these films is typically clearly lower than that of solar cells comprising the TCO layers produced with RF sputtering from ceramic targets.

### OBJECT AND SOLULTION

It is the object of the invention to provide transparent and conductive oxide layers (TCO layers) with improved optical and electrical film properties, which layers have a suitable surface structure for use in thin-film solar arrays. It is another object of the invention to provide a corresponding production method that is fast and usable on a large scale for the large-surface production of the afore-mentioned films.

The object is achieved with a method for producing a TCO layer having all the characteristics according to the main claim, with an improved TCO layer having the characteristics according to the additional independent claim, as well as with the use of a TCO layer of this type according to another independent claim. Advantageous embodiments of the method, the TCO layer and the use thereof are revealed in the corresponding claims relating to these claims.

### SUMMARY OF THE INVENTION

In reactive sputtering processes, the operating point is generally set such that the manufacturing process produces films with optimal electrical and optical properties. The idea underlying the present invention is based on the fact that the operating point for the sputtering process is set such that it is not oriented exclusively on the film to be produced directly following the production process, but instead includes the subsequent etching process that typically follows for solar cell applications.

The method according to the invention is a reactive sputtering method that uses a metallic Zn target. Power density levels of 5.3 W/cm² or 13 W/cm² are set that allow stationary deposition rates of more than 150 nm/min or more than 400 nm/min to be achieved. This corresponds approximately to dynamic deposition rates of more than 40 nm*m/min or more than 110 nm*min when using dual-magnetron cathodes.

The Zn target comprises a percentage of dopants. In addition to B, GA, In or F, aluminum is also a suitable dopant. The doping content in the target is generally less than 2.3 at-%, particularly less than 1.5 at-% and advantageously between 0.2 and 1 at-%. The doping content here relates only to the metallic component, which means that oxygen is not included. Accordingly, the content of aluminum is based on: Al/(Al+Zn).

The target is generally used as a previously doped target in the process. Alternatively, however, the target can be doped reactively during the process via the gaseous phase. This can be achieved particularly by adding boroethane B₂O₆ to the sputtering gases argon and oxygen.

A low doping content advantageously results in improved transmittance in the film being produced. Transmittance values generally relate to an averaged value across the spectral region of 400 to 1100 nm, meaning in the red and infrared spectral regions. At the same time, a low doping content reduces the concentration of the dopants, which also reduces the scattering effect in ionized interference locations and generally increases the mobility of the charge carriers. Aluminum has turned out to be a particularly effective doping agent.

The substrate is heated to temperatures above 200° C. Advantageous are temperatures above 250° C., particularly above 300° C. While in literature [2] an increased risk of Zn contamination is predicted with increasing substrate temperatures, and therefore substrate temperatures of no more than 150° C. are recommended, the high temperatures routinely do not result in impairment from contamination even when operating the method according to the invention over several months.

The production method generally requires monitoring of the reactive gas flow, or of the reactive gas partial pressure in the deposition room. Oxygen is used as the reactive gas, and argon and oxygen are used as the sputtering gases. Alternatively the use of ozone is also conceivable. In general, Ar is used for the non-reactive sputtering operation, and oxygen and argon are used for sputtering oxide layers. In order to stabilize different operating points of the reactive processes in the transition mode, a plasma emission monitor (PEM) is used. The intensity of the emission line of atomic zinc is analyzed in order to control the oxygen supply to the reaction volume. An operating point is characterized by a fixed intensity of the zinc emission. Another stabilization possibility, for example, is to control the oxygen partial pressure that can be measured with a Lambda sensor, for example.

Every operating point can result in a different material property of the ZnO:Al layer, particularly in different surface roughness levels, following the subsequent etching step. Therefore, initially ZnO layers are produced at different operating points in the preliminary stage, while otherwise maintaining the same process conditions. This means that with otherwise identical conditions such as deposition pressure, substrate temperature, output and film thickness, different stabilized operating points are set along the hysteresis or in the unstable hysteresis region and thus corresponding films are produced.

In order to stabilize different operating points of the reactive processes in the transition mode, a plasma emission monitor (PEM) is used. The intensity of the emission line of atomic zinc is analyzed in order to control the oxygen supply to the reaction volume. An operating point is characterized by a fixed intensity of the zinc emission.

With defined process parameters such as output, deposition pressure and temperature, the possible, stabilized operating points within the unstable process region have an S-shaped course. The operating point according to the invention is selected based on the following criteria:
it is located in the unstable hysteresis region and requires process control, and
it is located simultaneously in the upper, i.e. the metal, region of the hysteresis region.

The films produced this way, however, all have to meet certain minimum requirements in terms of transparency and conductivity. The resistivity should be less than 1*10⁻³ W cm, and the transmittance rate should be greater than 80%. The more oxidic the conditions, the greater the resistivity of the film in general.

Prior to any subsequent treatment, the ZnO layers produced with the method according to the invention particularly show the following properties:
The content of doping agent, particularly of aluminum, of the film that is produced is less than 3.5 at-%, advantageously even less than 3 at-%, particularly less than 2.5 at-% and more than 1.5 at-%.
The resistivity is smaller than 1*10⁻³ W particularly smaller than 5*10⁻⁴ W.
The charge carrier mobility is greater than 25 cm²/V s, particularly greater than 35 cm²/V s.
The transmittance rate is greater than 80%, advantageously greater than 82%. The transmittance values apply for the glass substrate system with film and are averaged across the range usable for silicon solar-modules between 400 nm and 1100 nm.

Following the production of the ZnO layer, subsequent treatment is carried out in the form of wet-chemical etching or dry etching. With this etching step, the surface of the ZnO layer becomes textured and is given a surface roughness that is responsible for allowing the high current density level when used in a silicon thin-film solar array. The method according to the invention produces an even surface roughness of the ZnO layer, for example an rms roughness of at least 30 nm and no more than 300 nm. The roughness generally increases with the etching duration up to a certain point. A lower roughness limit can be set from a nearly arbitrarily small value to an upper limit by varying the etching duration. At least more than 1 nm can be assumed as the lower limit, since a certain roughness is already present following the sputtering process. The upper limit depends on the developing surface structure.

The rms roughness of the method (δᵣₘₛ) following the etching process typically ranges between 30 nm and 300 nm. The rms roughness (root mean square roughness) is the mean roughness. For α:Si a mean roughness of 50 to 100 nm has proven to be advantageous, for microcrystalline silicon solar cells it ranges between 50 to 300 nm. For stacked solar cells comprising both solar cell types mean roughness values between 50 and 200 nm are advantageous.

It is only after this subsequent treatment step that the quality of the ZnO layer and the suitability as front contact for solar cells is verified most reliably by using it in a solar cell. During this process, particularly the photovoltaic characteristics are determined. This procedure is required because so far no reliable theoretical works exist that describe the properties of the film required for use in a solar cell in reliable terms. The etching conditions for the etching operation following the production of the ZnO:Al layers can be varied regardless of the layer properties. Therefore they are not part of the layer production parameters, on which the invention is based. Following etching, the surface structure is determine substantially by the layer properties per se. A fine optimization can be achieved by varying the etching duration. Also the selection of the etching medium, for example an acid or lye, may influence the final results. In general, diluted hydrochloric acid (HCl) is used for roughening the films.

So far, the operating point for the sputtering process is set such that the optical and electrical properties of the ZnO layer are optimal. In contrast, the operating point is used in the method according to the invention as a crucial parameter for controlling the etching behavior of the layers. As a result, the minimum requirements in terms of the electrical and optical properties are taken into consideration.

An advantageous embodiment of the method according to the invention provides for the use of a dual magnetron arrangement with medium frequency (mf) excitation. Furthermore, it has proven advantageous to carry out the method as a dynamic flow process, during which the substrate is moved back and forth beneath the carrier during sputtering.

### SPECIFIC DESCRIPTION

The object of the invention will be explained in more detail hereinafter with reference to the figures and exemplary embodiments, without limiting the object of the invention. Therein

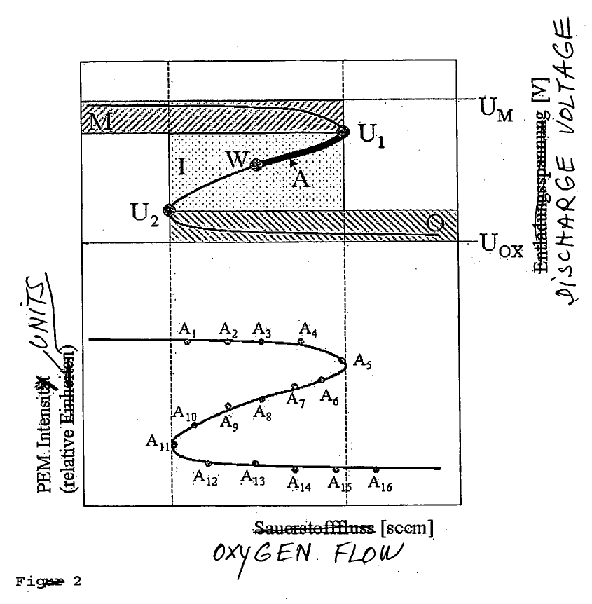

FIG. 2 shows transmittance of ZnO:Al layers;

FIG. 2 schematically shows discharge voltage (U) and plasma emission (PEM) intensity as a function of oxygen flow;

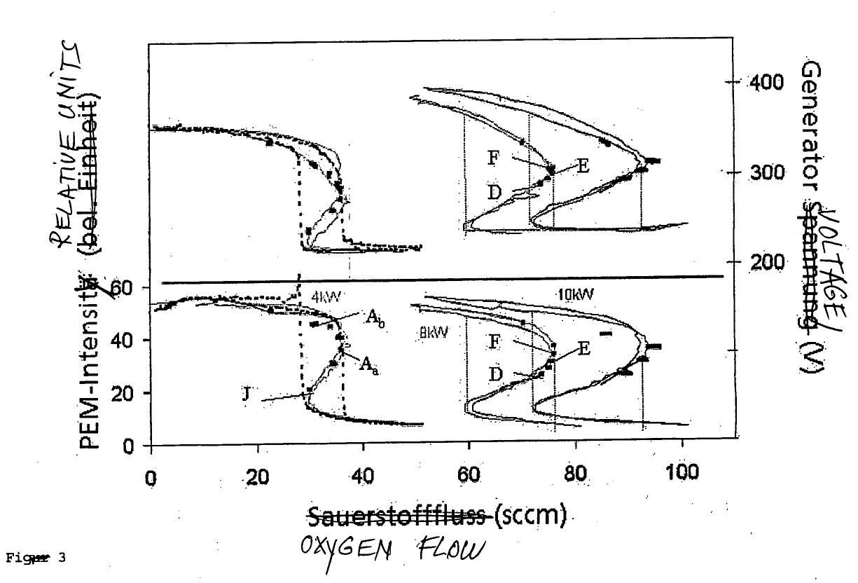

FIG. 3 shows generator voltage and plasma emission (PEM) intensity as a function of oxygen flow with designation of the operating point according to the invention;

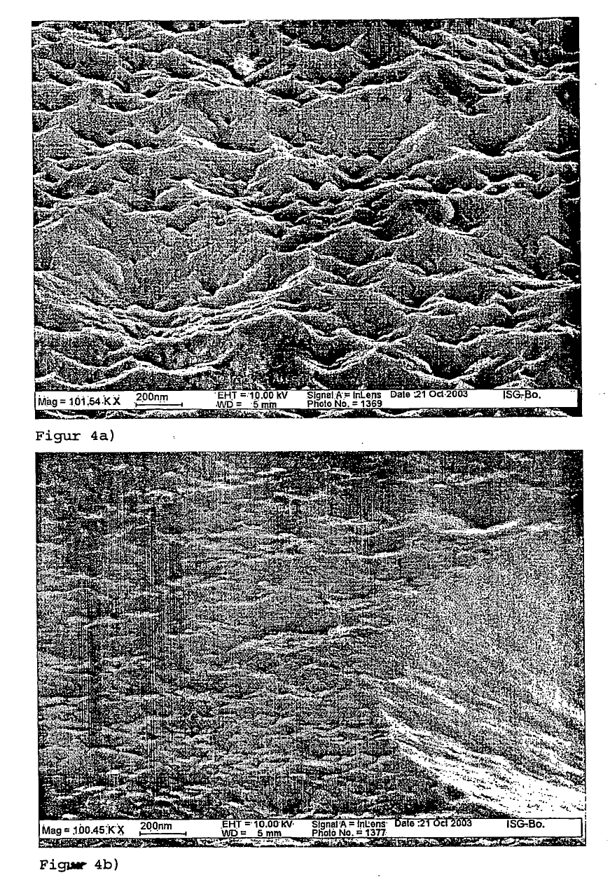

FIG. 4 shows SEM surface images of different ZnO layers following etching in diluted hydrochloric acid with FIG. 4a showing a film produced with operating point according to the invention and FIG. 4b showing a film produced with less than optimal operating point in metal region.

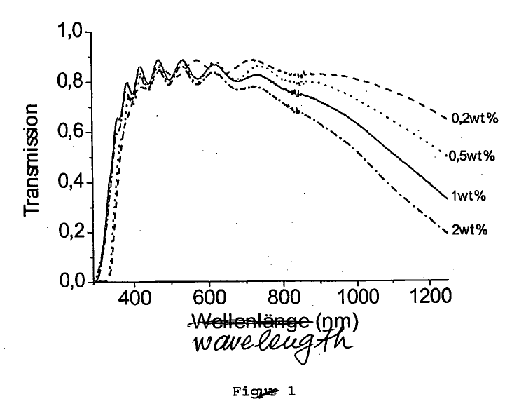

FIG. 1 shows the transmittance of ZnO:Al layers that were sputtered from targets with different aluminum content. In the red and infrared regions of the spectrum, the transmittance rate decreases with increasing aluminum content. For applications in microcrystalline silicon solar modules a high transparency value of up to about 1100 nm is required, so a low aluminum content is advantageous.

FIG. 2 is a schematic illustration of the hysteresis region (between the dotted lines) of the reactive sputtering process. In the case of low oxygen flow and high discharge voltage, the stable process window M is in the metal region, in the case of high oxygen flow and low discharge voltage, the stable process window is in the oxidic region O. U_{M} designates the discharge voltage during sputtering processes in the full metal region, Uₒₓ is the discharge voltage with fully oxidic processes. Additionally the following meanings apply for the upper part of FIG. 2:
Region I unstable process region where process control is required,
Region A process window for the operating points selected according to the invention with desired properties,
Region O stable process window in the oxidic region, and
Region M stable process window in the metal region.
Point U1 transition point between the stable, metal process and the unstable process
Point U2 transition point between the stable, oxidic process and the unstable process
Point W inflection point of the stabilized process curve.

In the lower part of the figure, individual operating points A₁ to A₁₆ have been entered on a process curve of the intensity of plasma emission (PEM) for atomic zinc versus oxygen flow. The operating points are defined by a constant PEM intensity with the oxygen flow as the control variable. The points A₅-A₇ designate operating points in the unstable region that are selected to be particularly suitable within the scope of the invention, while the operating points A₂ to A₄ produce optimal electrical properties in the produced films.

Different operating points have similar effects on the transmittance of the films, such as different aluminum contents, for example.

The more oxidic the selected operating point (low PEM intensity) is, the higher the transmittance rate in the red and infrared regions.

The region for suitable operating points selected within the scope of the invention can be designated in the upper part of FIG. 2 as the region on the process curve between U₁ and W. This means that process-controlled operating points should be set that are located in the unstable, metal region.

FIG. 3 illustrates this principle. Three series, each with different process parameters such as deposition pressure, output and temperature, have been entered versus oxygen flow. The upper part shows the entries versus the generator voltage that is proportional to the discharge voltage. The three illustrated curves show a curve progression that is shifted in relation to the X-axis that is caused by the different output levels of 4, 8 and 10 kw. In each series, the unstable process region is marked with dotted lines. In the curve in the center, additionally three select operating points D, E and F have been entered.

In the illustration of the three series shown in the lower part of FIG. 4 [sic] versus the PEM intensity additionally two further operating points Aₐ and A_{b} have been entered.

FIG. 4 shows the scanning electron microscopic (SEM) surface images of ZnO:Al layers that were produced at the above-mentioned operating points Aₐ and A_{b}. Following the production, the films were etched in diluted hydrochloric acid (HCl). FIG. 4a) shows a film image at the operating point Aₐ that was selected from the region according to the invention. The mean roughness is about 70 nm.

In contrast, the film at the operating point A_{b} shows a clearly reduced roughness that creates a significantly lower efficiency level when used in a solar cell.

The invention creates a method for producing conductive and transparent zinc oxide layers on a substrate, by reactive sputtering that consciously departs from the operating point for optimal electrical properties within a series and in contrast selects a operating point in the metal, unstable region of the process curve.

The table below shows the characteristics of solar cells produced within the scope of the invention, which cells were produced on different ZnO substrates. The characteristics listed are the plasma intensity PEM, the deposition rate, the resistivity p in the film prior to etching, the efficiency h, the space factor FF, the open-circuit voltage V_{oc} and the short circuit current density J_{sc}.

| | | | Deposition | Rho | | | | | |
|---|---|---|---|---|---|---|---|---|---|
| | | PEM | Rate | 10⁻⁴ | R_{square} | | | Voc | Jsc |
| Region | Layer | a.u. | nm * m/min | Ohm cm | Ohm | Eta % | FF % | mV | mA/cm² |
| A | A | 35 | 95 | 3.4 | 3.9 | 8.2 | 70.8 | 516 | 22.4 |
| A | B | 30 | 92 | 5.6 | 6.6 | 8.0 | 71.8 | 497 | 22.7 |
| A | C | 40 | 41 | 4.5 | 10 | 8.1 | 71.0 | 523 | 21.9 |
| A | D | 25 | 96 | 9.1 | 16.6 | 7.9 | 69.6 | 504 | 22.5 |
| A | E | 27.5 | 92 | 5.6 | 11.9 | 7.8 | 67.4 | 507 | 22.7 |
| A | F | 30 | 91 | 4.0 | 6.6 | 8.0 | 71.7 | 497 | 22.5 |
| M | G | 50 | 42 | 2.8 | 4.5 | 6.4 | 73.0 | 504 | 17.5 |
| M | H | 46 | 42 | 3.4 | 5.0 | 7.2 | 72.9 | 515 | 19.1 |
| M | I | 42 | 43 | 3.2 | 4.8 | 6.9 | 71.1 | 492 | 19.8 |
| P | J | 20 | 41 | 40000 | | | | | |
| K | K | 46 | 44 | 8.1 | 7.0 | 5.9 | 62.3 | 488 | 19.5 |
| K | L | 50 | 42 | 3.9 | 4.7 | 6.3 | 66.8 | 492 | 19.3 |
| K | M | 54 | 33 | 3.3 | 4.9 | 6.4 | 71.1 | 521 | 17.4 |
| Ref. | N | | 6 | 2.4 | 3.0 | 8.3 | 71.1 | 505 | 23.0 |

The layers are shown in the different regions of the hysteresis shown in FIG. 2 and the stabilization thereof. The different layers will be explained hereinafter.

The layers with rough etching were used as substrates in solar cells. The characteristics of some layers and of the solar cells on these substrate layers are listed in the table. Region A designates the layers produced according to the invention. The layers D-F show fine optimizations of the production parameters in this region. The layers G-I were produced in the metal region of the reactive process at the upper section of the hysteresis curve that corresponds to the present state of the art and supplies electrically the best layers.

The modified etching behavior and the resulting surface roughness may increase the electricity yield in the solar cells considerably (see Regions A and M). Losses as a result of the increased resistivity on the other hand limit the efficiency of the solar cells in oxidically sputtered films. Film J (Region O) that due to the high resistivity is not suited as a contact layer, represents the extreme case. The changed electricity yield as a result of the operating point should be considered independently from the remaining production parameters, such as the substrate temperature and deposition pressure. The open-circuit voltage of the solar cells can be easily influenced by the substrate that is used. This effect, however, is comparatively low. The layers K-M with the designation K were produced at substrate temperatures of Tₛ<220° C. and clearly demonstrate that a high substrate temperature is necessary in order to produce good ZnO:Al substrate layers for silicon solar cells. All characteristics of solar cells on a substrate that has been sputtered at temperatures that were too cold show deficits that are reflected in poor efficiency. A non-reactively sputtered layer N is provided as a comparison layer. The layer N shows the best properties in the solar cells, however cannot be used cost effectively for the industrial production of solar modules due to the low deposition rate (Factor 10). The latter and the layers from the Region A according to the invention show good efficiency levels of 8% and higher in the solar cells.

State of the art cited in this application:

[1] J. Müller et al, State-of-the-art mid-frequency sputter ZnO films for thin-film silicon solar cells and modules, Thin Solid Films 442 (2003) 158-162.

[2] B. Szyszka et al., Transparent and conductive ZnO:Al films deposited by large area reactive magnetron sputtering, Thin Solid Films 442 (2003) 179-183.

1. A method for producing a conductive and transparent zinc oxide layer on a substrate by reactive sputtering, the process having a hysteresis region, characterized by the following steps:
a metallic Zn target with doping is used, the doping content of the target being less than 2.3 at-%,
the heater for the substrate is set such that a substrate temperature of greater than 200° C. is set,
a dynamic deposition rate of greater than 50 nm*m/min is set that corresponds to a static deposition rate of more than 190 nm/min, and
a stabilized operating point within the unstable process region is selected that is located between the transition point between a stable, metal process and an unstable process and the inflection point of the stabilized process curve.

2. The method according claim 1 wherein a target with a doping content of less than 1.5 at-%, particularly of less than 1 at-% is used.

3. The method according to claim 1 wherein a target with aluminum as the doping agent is used.

4. The method according to claim 1 wherein the substrate is heated to temperatures above 250° C., particularly to temperatures above 300° C.

5. The method according to claim 1 wherein a dynamic deposition rate of greater than 80 nm*m/min, particularly of greater than 100 nm/min is set that corresponds to a static deposition rate of greater than 300, particularly greater than 380 nm/min.

6. The method according to claim 1 wherein a dual magnetron arrangement with medium frequency (mf) excitation is used.

7. The method according to claim 1 wherein a dynamic flow process is carried out, where the substrate is moved during sputtering.

8. A conductive and transparent zinc oxide layer, produced with the method according to claim 1, characterized in that the content of doping agent, particularly of aluminum, in the produced oxide layer is less than 3.5 at-%, that the resistivity is less than 1*10⁻³ W cm, that the charge carrier mobility is greater than 25 cm²/V s and that the averaged transmittance of 400 to 1100 nm is greater than 80%.

9. The oxide layer according to claim 8 wherein the content of doping agent is less than 3 at-%, particularly less than 2.5 at-%.

10. The oxide layer according to claim 8 wherein the resistivity is less than 5*10⁻² W cm.

11. The oxide layer according to claim 8 wherein the charge carrier mobility is greater than 35 cm²/V s.

12. The oxide layer according to claim 8 wherein the averaged transmittance of 400 to 1100 nm is greater than 82%.

13. The oxide layer according to claim 8 wherein the layer comprises aluminum as the doping agent.

14. Use of an oxide layer according claim 8 in a solar cell.

15. The use according to claim. 14 in a crystalline silicon thin-film solar array.

16. The use according to claim 14 in an amorphous and crystalline silicon tandem solar array.
